(19) United States
(12) Patent Application Publication
(10) Pub. No.: US 2026/0023906 A1
(43) Pub. Date: Jan. 22, 2026

(54) POST-IMPLEMENTATION MASKING VERIFICATION OF A SOURCE DESIGN OF A CIRCUIT

(71) Applicant: Arm Limited, Cambridge (GB)

(72) Inventor: Alexander Klimov, Hadera (IL)

(21) Appl. No.: 18/779,630

(22) Filed: Jul. 22, 2024

(51) Int. Cl. G06F 30/3323

(52) U.S. Cl. CPC G06F 30/3323

(57) ABSTRACT

A method for post-implementation masking verification of a source design of a circuit includes receiving a gate level netlist of a source design of a circuit having masking and evaluating intermediate nets of the netlist of the source design for a broken masking of an input. Evaluating intermediate nets of the netlist of the source design for broken masking of an input is performed for each implicit input associated with the input of the netlist of the source design of the circuit. For each implicit input, each of M random values for a share of each implicit input is applied as input to the netlist. When it is determined that the intermediate nets of the netlist do not satisfy a masking criteria using tracked intermediate net values, indicating that the intermediate net of the netlist is broken.

### BACKGROUND

Electronic design automation (EDA) tools assist in the design, implementation, verification, and subsequent manufacturing of semiconductor devices that includes circuitry. Circuits can be designed using the EDA tools in a hardware description language, such as Verilog.

During a circuit design process, some components are custom created while other components are obtained from standard cell libraries or part of packages from another design team and imported into a design. One example of a circuit that can be part of a package from another design team is a masking circuit, which is a useful protection against side channel attacks. Side channel attacks (SCAs) refer to a set of attack techniques that may be used to compromise the security of a circuit or other computing device. SCAs generally include attacks based on information gained from the physical implementation of the circuit, including timing information, power consumption, electromagnetic leaks, and sound.

Masking involves avoiding manipulating sensitive values directly. Instead, the sensitive values are split into values known as shares. The shares can be assigned random values while still maintaining a relationship to the secret value. The shares can then be manipulated in intermediate operations. The intermediate results of the intermediate operations should be independent of the sensitive value.

Sometimes during the implementation of the circuit in the circuit design process, in order to optimize the layout or other features of the design, the EDA tool may change the order of operations and break the masking that was part of the package from the other design team. There are methods to verify that the final circuit is functionally equivalent to its source design, for example logical equivalence checking, however, a circuit with broken masking can be equivalent to a properly masked circuit. This can result in a circuit design that does not perform as intended.

### BRIEF SUMMARY

Methods for post-implementation masking verification of a source design of a circuit are provided. Through processes described herein, it can be determined if the masking of a source design of a circuit has been broken after an implementation stage of circuit design. The methods for post-implementation masking verification can be instructions implemented in Verilog and run with, e.g., as a plug-in tool, or on the EDA tool itself. This simplifies the verification process for masking correctness for the designer. In addition, having both the EDA tool and a process to verify masking correctness implemented in the same language, e.g., Verilog, prevents an expertise mismatch.

A computer-implemented method for post-implementation masking verification of a source design of a circuit includes receiving a gate level netlist of a source design of a circuit having masking and evaluating intermediate nets of the gate level netlist of the source design for a broken masking of an input. Evaluating intermediate nets of the gate level netlist of the source design for broken masking of an input is performed for each implicit input associated with the input of the gate level netlist of the source design of the circuit. For each implicit input, each of M random values for a share of each implicit input is applied as input to the gate level netlist. For each of the M random values, an intermediate net value is tracked at each intermediate net resulting from the application of the random value for the share. It is determined whether the intermediate nets of the gate level netlist satisfy a masking criteria using the tracked intermediate net values. When an intermediate net of the gate level netlist does not satisfy the masking criteria, indicating that the intermediate net of the gate level netlist is broken.

A computer-readable medium including instructions stored thereon is provided. The instructions when executed by a computing system direct the computing system to receive a gate level netlist of a source design of a circuit having masking and evaluate intermediate nets of the gate level netlist of the source design for a broken masking of an input. Evaluating intermediate nets of the gate level netlist of the source design for broken masking of an input is performed for each implicit input associated with the input of the gate level netlist of the source design of the circuit. For each implicit input, each of M random values for a share of each implicit input is applied as input to the gate level netlist. For each of the M random values, an intermediate net value is tracked at each intermediate net resulting from the application of the random value for the share. It is determined whether the intermediate nets of the gate level netlist satisfy a masking criteria using the tracked intermediate net values. When an intermediate net of the gate level netlist does not satisfy the masking criteria, indicating that the intermediate net of the gate level netlist is broken.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

FIG. 1 illustrates a representational diagram depicting stages of design of a circuit using an EDA tool.

FIG. 2 illustrates a flowchart of a method for post-implementation masking verification of a source design of a circuit.

FIG. 3 illustrates an example graphic user interface of an EDA tool.

FIG. 4 illustrates a schematic diagram illustrating components of a computing device.

### DETAILED DESCRIPTION

Methods for post-implementation masking verification of a source design of a circuit are provided. Through processes described herein, it can be determined if the masking of a source design of a circuit has been broken after an implementation stage of circuit design.

Electronic circuits can be designed in software using hardware description languages such as Verilog. The hardware description language allows a user to create a formal description of the electronic circuit, e.g., an RTL (register transfer level) design, that can be synthesized and simulated prior to the production of actual hardware such as an integrated circuit. The hardware description language forms a part of the EDA tool used for creating circuits such as complex digital circuits that can include application specific integrated circuits (ASICs) and programmable logic devices (e.g., field-programmable gate arrays (FPGAs)). A test bench is a simulation environment used to verify the functionality and correctness of a circuit design described in the hardware description language. The test bench can be a Verilog test bench. Methods for post-implementation masking verification proposed herein can be implemented on such a test bench.

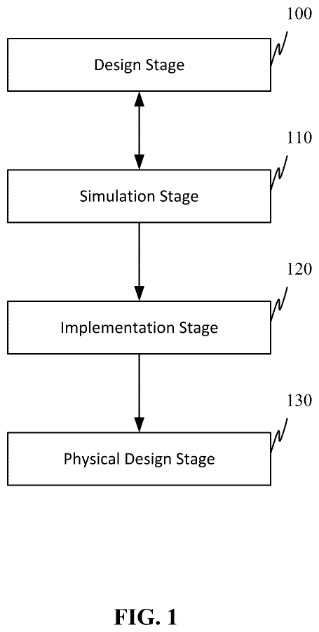

FIG. 1 illustrates a representational diagram depicting stages of design of a circuit using an EDA tool. Referring to FIG. 1, in a design stage 100, a designer designs the circuit which can be first designed as a schematic providing a graphical representation of the circuit, showing components and interconnections of the circuit and transformed into an RTL description creating a source design of the circuit. The RTL description can be represented in a hardware description language (e.g., VHDL or Verilog) which can then be further refined to precisely represent the circuit, specifying data flow and operations of the systems. A simulation stage 110 allows the designer to simulate and verify the operation of the source design of the circuit. In an implementation stage 120, the RTL source design is transformed into a gate level representation, such as a gate level netlist, that describes the connectivity of the circuit. The netlist includes instances which represent logic blocks comprising gates connected between terminals by intermediate nets, e.g., wires. In the implementation stage 120, a mathematical method is performed to verify the correctness of the RTL source design. During the implementation stage 120, optimizations can be performed on the source design e.g., the logic blocks, for better performance of the circuit, for example through routing and power connections. Lastly, a physical layout of the optimized RTL source design of the circuit can be created in a physical design stage 130.

Masking is a cryptographic countermeasure used to resist side channel attacks. Masking techniques can be applied to the gate level netlist that involves avoiding manipulation of any sensitive value directly, but rather manipulates shares of the sensitive value (helping to obfuscate the sensitive values). An attacker would have to recover all the values of the shares to obtain any meaningful information, thus, making an attack to obtain sensitive information much more difficult.

In a masking process, each sensitive value is split into two or more randomized shares and computations are performed with the shares. For example, if the sensitive value is x, the shares can be x1, . . . xd, such that x=x1+ . . . +xd (where “+” indicates an XOR operation). An XOR gate is a logic gate that produces a one if and only if exactly one of the bits is a one. The XOR operation can be used in generating parity bits for error checking and fault tolerance.

During the implementation stage 120 of the source design of the circuit, e.g., when a mathematical method is performed on the netlist of the source design to verify correctness of the source design having masking, it is not sufficient to only check the output because any intermediate result (which can represent an intermediate net of the netlist) of an operation of the mathematical method needs to be independent of the sensitive value to preserve the masking. That is, for every intermediate value y, and constants A, B, and Y, the probability that y=Y if x=A is the same as the probability that y=Y if x=B. Written in equation form:

Pr[y=Y|x=A]=Pr[y=Y|x=B] (1).

Consider an example of masking with two shares assigned for each sensitive value, x and y. Instead of directly computing

z=x*y (2),

x can be split into two shares, xp (x prime) and xs (x star).

Randomness, in the form of random values, can be inserted into the mathematical method to create some ambiguity while still maintaining accurate mathematical relationships. For example, a random value r1 is assigned to xp and r1+x is assigned to xs.

xp=r1 (3).

xs=r1+x (4).

Likewise, y is split into two shares, yp (y prime) and ys (y star). A random value r2 is assigned to yp and r2+y is assigned to ys.

yp=r2 (5)

ys=r2+y (6).

An indirect calculation of the implicit value z=x*y including shares of z and random values can be:

z=zp+zs=(xp+xs)(yp+ys)=x*y (7)
where zp=r3+xp*yp+xp*ys and zs=r3+xs*yp+xs*ys.

All of the values in the two equations are independent of the secret values, x and y. In addition, each intermediate result, I (e.g., r3+xp*yp) is also independent of the secret values x and y. For zp and zs, each intermediate result includes an XOR with a random value r3.

The probability that the random value r3 has a value of one is one half and the probability that the random value r3 has a value of zero is one half.

Pr[r3=0]=Pr[r3=1]=0.5 (8).

As stated above, an intermediate result I can be represented as I=r3+xp*yp.

Pr[I=0|A=0]=Pr[r3+A=0|A=0]=Pr[r3=0]=0.5 (9).

Pr[I=1|A=0]=Pr[r3+A=1|A=0]=Pr[r3=1]=0.5 (10).

Thus, Pr[I=0|A=0]=Pr[I=1|A=0].

Similar for A=1. Thus, Pr[I=0|A=0]=Pr[I=0|A=1].

If, during the implementation stage 120, the EDA changes the order of operations when optimizing the circuit, the equation for zp described above can become:

zp=r3+(xp*yp+xp*ys) (11).

The masking has become broken because for the parenthesized expression the probability is different for different values of y:

I=xp*yp+xp*ys=xp*(yp+ys)=xp*y (12).

Pr[I=0|y=0]=1 (13)

Pr[I=1|y=0]=0 (14).

Pr[I=0|y=1]=P[xp=0]=0.5< >1 (15).

Thus, a challenge when utilizing masking in circuit design is that during an implementation step when optimizations are performed, the EDA tool can break the masking with the result that the final physical circuit is vulnerable to side channel attacks. To check that the masking has not been broken during the implementation stage 120 of the circuit design when the optimizations are performed, methods can be performed in which values on the intermediate nets are checked to verify that these values randomly change when testing the source design with an input.

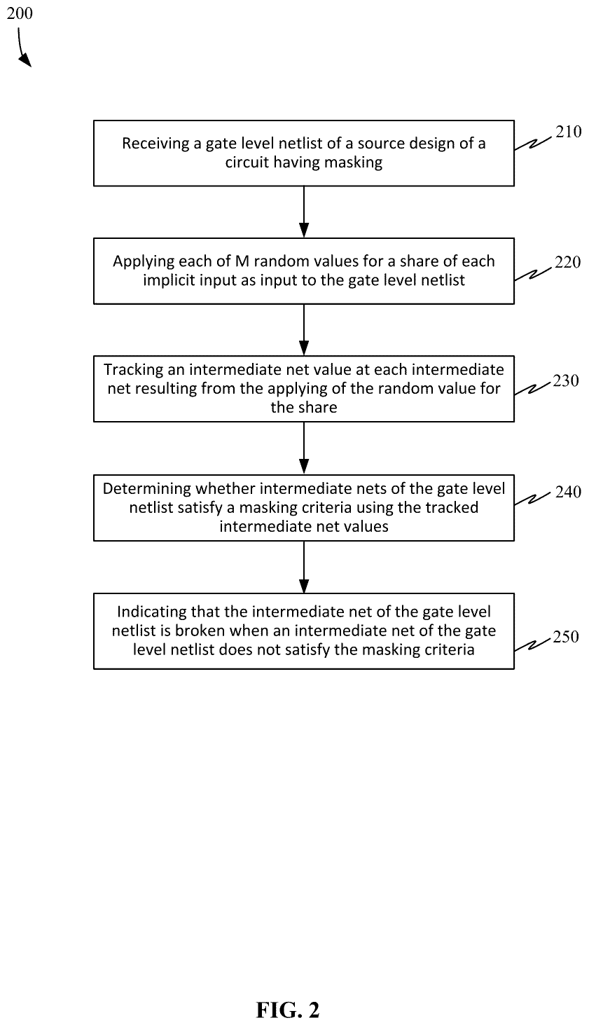

FIG. 2 illustrates a method for post-implementation masking verification of a source design of a circuit. Referring to FIG. 2, method 200 may begin upon receiving (210) a gate level netlist of a source design of a circuit having masking. The code of method 200 can be integrated directly into the software of the EDA tool and performed after the implementation stage 120 of the source design of the circuit to verify that the masking has not been broken.

The verification of the masking can be accomplished by evaluating all the intermediate nets of the gate level netlist of an input for broken masking. A sampling of the random values for a share of each implicit value associated with the input can be applied (220) to the gate level netlist of the source design of the circuit. For example, M random values for the share can be applied as the input to the gate level netlist. In some cases, M can be greater than 30. As an illustrative example, the implicit inputs can be all the inputs from an 8-bit S-box, which is a logic computing component for cryptographic circuits.

For each of the M random values, an intermediate net value at each intermediate net of the gate level netlist is tracked (230) resulting from the applying of the random value for the share. After each random value for the share of the implicit input has been applied as input to the gate level netlist, it can be determined (240) whether intermediate nets of the gate level netlist satisfy a masking criteria using the tracked intermediate net values. When an intermediate net of the gate level netlist does not satisfy the masking criteria, method 200 indicates (250) that the intermediate net of the gate level netlist is broken.

In some cases, tracking (230) the intermediate net value for each intermediate net includes checking a value of the intermediate net and marking that value as “seen as a one” or “seen as zero”. When both possible values of the intermediate net are marked as seen, e.g., the intermediate net value on the intermediate net changes at least once, the masking criteria is determined (240) to be satisfied.

As an illustrative example, pseudocode for such a process is as follows:
for every implicit input {for
   M=100 random inputs {
   apply the inputs to the tested circuit
      for every intermediate net {if
         the net is 0, mark it as “seen as 0”
         if the net is 1, mark it as “seen as 1”}
      }
   {
   for every intermediate net {
   report “broken masking” unless the intermediate net is “seen as 0” and “seen as 1”}
}

In other cases, tracking (230) intermediate net values includes checking a value of the intermediate net and incrementing a count of when the value is one. In some of such cases, determining (240) that the masking criteria is satisfied includes checking, based on the count, that for different implicit inputs, estimated probabilities of an intermediate net to be one are approximately equal. When the estimated probabilities of an intermediate net to be one are approximately equal, the masking criteria is determined to be satisfied. The probabilities are considered estimated because only a sampling of the random values for a share of each implicit value associated with the input are applied. It can be assessed that the ‘real’ probabilities, e.g., the probabilities calculated using all of the random values, are approximately equal by comparing the estimated probabilities.

The estimated probability of each intermediate net to be one is checked to be independent of the sensitive input. To do this, for each implicit input of each intermediate net, (A) the probability that the intermediate net is one is estimated for the particular implicit input, (B) the probability that the intermediate net is one in general, e.g., find an average for all implicit inputs, (C) calculate deviations, that is, how different each estimated probability in (A) is from the estimated probability in (B), and (D) perform a statistical test to check that such a deviation can be seen by chance in a perfectly masked circuit, that the real probabilities are equal. Checking, based on the count, that for different implicit inputs estimated probabilities of an intermediate net to be one are approximately equal includes: calculating an average of counts from each random value for a share of each implicit input for the intermediate net, calculating a deviation for each count from the average and performing a statistical test using the deviation to assess the equality. In some cases, M=4096 random values. Utilizing a probability calculation for a value on an intermediate net gives a more accurate indication of whether the masking is broken than simply checking that the value on the intermediate net changes.

For example, let N be the number of intermediate nets. Four integer arrays can be maintained, cnt[N], (count for each intermediate net for one implicit input), cnt_total[N] (total count for all implicit inputs for each intermediate net), cnt_min[N] (minimal deviation of the count for each intermediate net), cnt_max[N] (maximal deviation of the count for each intermediate net). cnt_min is initialized with M in each element, while the other integer arrays are initialized with zero.

As an illustrative example, pseudocode for such a process is as follows:
for each possible implicit input V (e.g., K=256 possibilities) {
   initialize cnt with all zeros
   repeat M=4096 times {
      randomly set circuit inputs so that the implicit input is V
      for every intermediate net i {
         cnt[i]+=intermediate net[i]//add one if the intermediate net is one
         }
   {
// cnt[i]/M is the estimation (A)
   for every intermediate net {
   cnt_total[i]+=cnt[i]
   if cnt_min[n]>cnt[n], then cnt_min[n]=cnt[n]
   if cnt_max[n]<cnt[n], then cnt_max[n]=cnt[n]
      }
}
   The average, avg[i]=cnt_total[i]/(M*K), is the estimation (B). Values avg[i]−cnt_min[i]/M and cnt_max[i]/M−avg[i] are deviations of the estimations (C) used to assess the plausibility of the equality of precise probabilities using the estimated probabilities. Statistical testing (D) can be performed using the deviations to check that the deviations are not larger than expected for the binomial distribution.

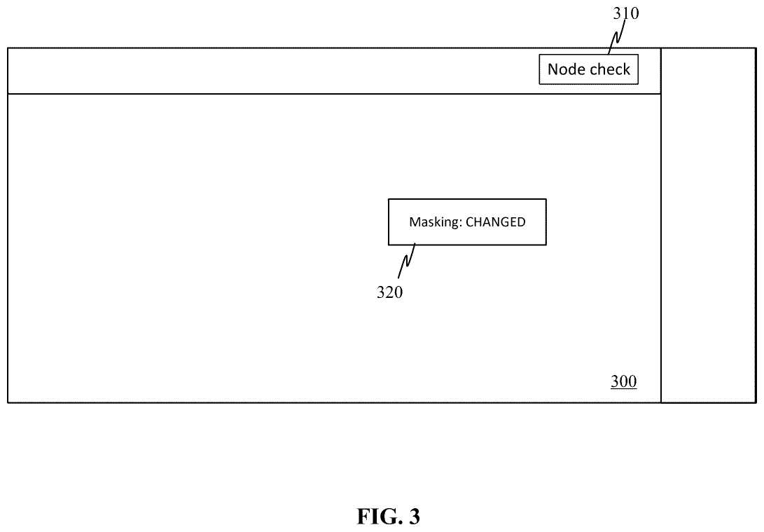

FIG. 3 illustrates an example graphic user interface of an EDA tool. Referring to FIG. 3, the example graphic user interface 300 can be the interface of an EDA tool in which various operations of design implementation are carried out. In some cases, the designer can interact with graphic user interface 300, for example by selecting a node check command 310, to run described methods for post-implementation masking verification of a source design of a circuit. The node check command 310 can trigger a plug-in or be part of the EDA tool itself. In response to the selection of the node check command 310 method 200 can be performed. The result of the method can be shown, for example, in a window/dialog box 320 to indicate (250) that the masking is broken, e.g., Masking: Changed, or not broken, e.g., Masking: Not Changed. It should be understood that the illustrated example is merely representative of potential functionality of an EDA tool and corresponding graphic user interface. In addition, different mechanisms for accessing method 200 may be provided, along with different interfaces and visual cues. For example, a stand-alone tool may also be provided.

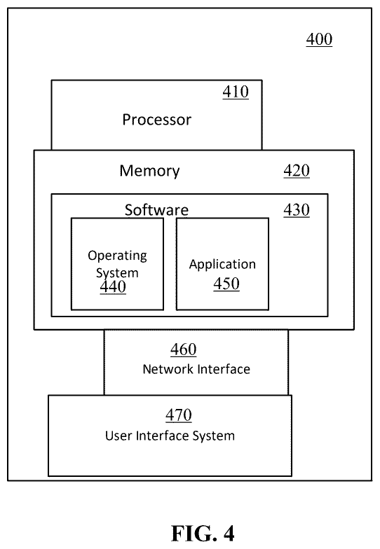

FIG. 4 illustrates a schematic diagram illustrating components of a computing device that may be used in certain implementations described herein. The computing device can be representative of a computing device on which an EDA tool runs as well as the methods for post-implementation verification of the source design of a circuit as described herein. Referring to FIG. 4, computing device 400 (or “computing system”) can represent a personal computer, a mobile device, a tablet, a laptop computer, a desktop computer, a server, or a smart television as some examples. Accordingly, more or fewer elements described with respect to computing device 400 may be incorporated to implement a particular computing device.

Referring to FIG. 4, computing device 400 can include at least one processor 410, a memory 420, software 430 that includes operating system 440 and application 450 stored in the memory 420, network interface 460, and user interface 470. Processor 410 processes data and performs operations according to instructions of software 430. The instructions of application 450 may be loaded into computing device 400 and run on or in association with the operating system 440. Application 450 can include the methods as described (e.g., method 200), the EDA tool, or both (e.g., the methods integrated into the EDA tool, a plug-in and the EDA tool, separate applications, etc.). Memory 420 may comprise any computer readable storage media readable by processor 410 and capable of storing software 430 including application 450. Memory 420 (and any computer readable storage media forming memory 420) does not consist of propagating signals nor is considered transitory media.

Computing device 400 can further include a user interface 470, which may include input/output (I/O) devices and components that enable communication between a user and the computing device 400 such as, but not limited to, a display, keyboard, mouse, microphone, and speakers. Computing device 400 may also include a network interface 460 that allows the system to communicate with other computing devices, including server computing devices and other client devices, over a network. Network interface 460 can include wired and/or wireless interfaces of one or more communication protocols and/or ports (e.g., for wifi or Ethernet, BLUETOOTH, near field communication (NFC), etc.)

Concepts described herein post-implementation masking verification of a source design of a circuit may be embodied in computer-readable code that embodies the described concepts. The computer-readable code may enable the definition, modelling, simulation, verification and/or testing of an apparatus embodying designs and concepts described herein.

The computer-readable code embodying the concepts described herein, including masking verification of a source design of a circuit, can be embodied in code defining a hardware description language (HDL) representation of the concepts. For example, the code may be in Verilog, System Verilog, Chisel, or VHDL (Very High-Speed Integrated Circuit Hardware Description Language) as well as intermediate representations such as FIRRTL. The computer-readable code may provide definitions embodying the concept using system-level modelling languages such as SystemC and System Verilog or other behavioral representations of the concepts that can be interpreted by a computer to enable simulation, functional and/or formal verification, and testing of the concepts. A computer-readable medium storing such computer-readable code does not consist of propagating waves nor is considered a transitory media.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts that would be recognized by one skilled in the art are intended to be within the scope of the claims.

What is claimed is:

1. A computer-implemented method for post-implementation masking verification of a source design of a circuit, the method comprising:
receiving a gate level netlist of a source design of a circuit having masking;
evaluating intermediate nets of the gate level netlist of the source design for a broken masking of an input by:
for each implicit input associated with the input of the gate level netlist of the source design of the circuit:
for each of M random values for a share of the implicit input:
applying the random value for the share of the implicit input as the input to the gate level netlist;
tracking an intermediate net value at each intermediate net resulting from the applying of the random value for the share;
determining whether intermediate nets of the gate level netlist satisfy a masking criteria using the tracked intermediate net values; and
upon an intermediate net of the gate level netlist not satisfying the masking criteria, indicate that the intermediate net is broken.

2. The computer-implemented method of claim 1, wherein tracking the intermediate net value includes checking a value of the intermediate net and marking that value as seen as a one or seen as zero, and wherein when both possible values of the intermediate net are marked as seen, the masking criteria is determined to be satisfied.

3. The computer-implemented method of claim 1, wherein M is greater than 30.

4. The computer-implemented method of claim 1, wherein tracking the intermediate net value includes checking a value of the intermediate net and incrementing a count when the value is one, wherein determining whether each intermediate net of the gate level netlist satisfies a masking criteria includes checking, based on the count, that for different implicit inputs, estimated probabilities of an intermediate net to be one are approximately equal, and wherein when the estimated probabilities of an intermediate net to be one are approximately equal, the masking criteria is determined to be satisfied.

5. The computer-implemented method of claim 4, wherein checking, based on the count, that for different implicit inputs, estimated probabilities of an intermediate net to be one are approximately equal includes:
calculating an average of counts from each random value for a share of each implicit input for the intermediate net;
calculating a deviation for each count from the average; and
performing a statistical test using the deviation to assess the equality.

6. The computer-implemented method of claim 1, wherein each implicit value associated with the input of the gate level netlist of the source design of the circuit are inputs from an 8-bit S-box.

7. The computer-implemented method of claim 1, wherein the computer-implemented method is performed after an implementation stage of circuit design in an electronic design automation (EDA) tool.

8. The computer-implemented method of claim 7, wherein the computer-implemented method is implemented on a test bench.

9. A computer-readable medium comprising instructions stored thereon, the instructions when executed by a computing system direct the computing system to:
receive a gate level netlist of an RTL of a source design of a circuit having masking;
evaluate intermediate nets of the gate level netlist of the source design for a broken masking of an input by:
for each implicit input associated with the input of the gate level netlist of the source design of the circuit:
for each of M random values for a share of the implicit input:
apply the random value for the share of the implicit input as the input to the gate level netlist;
track an intermediate net value at each intermediate net resulting from the applying of the random value for the share;
determine whether intermediate nets of the gate level netlist satisfy a masking criteria using the tracked intermediate net values; and
upon an intermediate net of the gate level netlist not satisfying the masking criteria, indicate that the intermediate net is broken.

10. The computer-readable medium of claim 9, wherein the instructions are in a same language as that of a test bench.

11. The computer-readable medium of claim 10, wherein the instructions are in Verilog.

12. The computer-readable medium of claim 9, further comprising an electronic design automation (EDA) tool stored thereon.

13. The computer-readable medium of claim 9, wherein instructions to track the intermediate net value direct the computing system to:
check a value of the intermediate net and mark that value as seen as a one or seen as zero, and
wherein when both possible values of the intermediate net are marked as seen, the masking criteria is determined to be satisfied.

14. The computer-readable medium of claim 9, wherein instructions to track the intermediate net value direct the computing system to check a value of the intermediate net and incrementing a count when the value is one,
wherein instructions to determine whether each intermediate net of the gate level netlist satisfies a masking criteria direct the computing system to check, based on the count, that for different implicit inputs, estimated probabilities of an intermediate net to be one are approximately equal, and wherein when the estimated probabilities of an intermediate net to be one are approximately equal, the masking criteria is determined to be satisfied.

15. The computer-readable medium of claim 14, wherein instructions to check, based on the count, that for different implicit inputs, estimated probabilities of an intermediate net to be one are approximately equal directs the computing system to:
calculate an average of counts from each random value for a share of each implicit input for the intermediate net;
calculate a deviation for each count from the average; and
perform a statistical test using the deviation to assess the equality.

16. The computer-readable storage medium of claim 9, wherein each implicit value associated with the input of the gate level netlist of the source design of the circuit are inputs from an S-box.

17. A computing system, comprising:
a processor;
a memory; and
instructions stored on the memory that when executed by the processor direct the processor to:
receive a gate level netlist of an RTL of a source design of a circuit having masking;
evaluate intermediate nets of the gate level netlist of the source design for a broken masking of an input by:
for each implicit input associated with the input of the gate level netlist of the source design of the circuit:
for each of M random values for a share of the implicit input:
apply the random value for the share of the implicit input as the input to the gate level netlist;
track an intermediate net value at each intermediate net resulting from the applying of the random value for the share;
determine whether intermediate nets of the gate level netlist satisfy a masking criteria using the tracked intermediate net values; and
upon an intermediate net of the gate level netlist not satisfying the masking criteria, indicate that the intermediate net is broken.

18. The computing system of claim 17, wherein the instructions are in a same language as that of a test bench.

19. The computing system of claim 18, wherein the instructions are in Verilog.

20. The computing system of claim 17, further comprising an electronic design automation (EDA) tool stored thereon.
